(19) United States
(12) Patent Application Publication
(10) Pub. No.: US 2011/0259386 A1
(43) Pub. Date: Oct. 27, 2011

(54) THERMOELECTRIC GENERATING MODULE

(76) Inventors: Yueh-Mu Lee, Taoyuan County (TW); Hwen-Fen Hong, Taoyuan County (TW); Hwa-Yuh Shin, Taoyuan County (TW); Zun-Hao Shih, Taoyuan County (TW)

(21) Appl. No.: 12/839,799

(22) Filed: Jul. 20, 2010

(30) Foreign Application Priority Data
Apr. 23, 2010 (TW) 099112923

(51) Int. Cl. H01L 35/02

(52) U.S. Cl. 136/206

(57) ABSTRACT

A thermoelectric generating module includes at least one thermoelectric unit and at least one light-concentrating unit. The thermoelectric unit has a first surface and a second surface disposed oppositely. The light-concentrating unit is disposed adjacent to the thermoelectric unit and concentrates light on the first surface of the thermoelectric unit.

### CROSS REFERENCE TO RELATED APPLICATIONS

This Non-provisional application claims priority under 35 U.S.C. §119(a) on Patent Application No(s). 099112923 filed in Taiwan, Republic of China on Apr. 23, 2010, the entire contents of which are hereby incorporated by reference.

### BACKGROUND OF THE INVENTION

1. Field of Invention

The invention relates to a power generating module and, in particular, to a thermoelectric generating module.

2. Related Art

Due to the crisis of exhaustion of non-renewable energy and the global upsurge of environmental consciousness, exploitation of renewable energy has become a very important subject nowadays. Because solar energy is inexhaustible in supply and always available for use, the technology of power generation by making use of solar energy is developed recently.

In general, there are two ways to transform solar energy into electricity. One is that the semiconductor unit receives the photon energy from solar light to generate current, and this is called photoelectric power generation. The other is that the thermoelectric material receives and converts the thermal energy from solar light to the electric energy, and this is called thermoelectric power generation.

Regarding to the thermoelectric power generation, it started from the discovery of thermoelectric effect disclosed by physicist. The discovery teaches that a current loop can be created in a closed loop formed of two metals joined in two ends with a temperature difference between the junctions. In the beginning, because the thermoelectric effect in such metals is weak, it just can be applied to the measurement of temperature or radiation energy. For example, a thermocouple, a typical case applying thermoelectric effect, is commonly used in factories and laboratories for measuring temperature. Until the end of the 1950s, some semiconductor materials were discovered to have strong thermoelectric effect, and thus the applications of thermoelectric effect began to be valued highly. In such applications, p-type semiconductor and n-type semiconductor replace the metals and are connected in series to form the thermoelectric generating device. Based on Seebeck effect, the thermoelectric generating device can generate a current according to the provided temperature difference.

Therefore, it is a very important subject to provide a thermoelectric generating module that can enhance efficiency of power generation.

### SUMMARY OF THE INVENTION

In view of the foregoing subject, an object of the invention is to provide a thermoelectric generating module that can enhance efficiency of power generation.

To achieve the above object, a thermoelectric generating module according to the invention includes at least one thermoelectric unit and at least one light-concentrating unit. The thermoelectric unit has a first surface and a second surface disposed oppositely. The light-concentrating unit is disposed adjacent to the thermoelectric unit and concentrates light on the first surface of the thermoelectric unit.

As mentioned above, in the thermoelectric generating module of the invention, the light-concentrating unit concentrates light on the thermoelectric unit, so that the thermal energy of the light can be concentrated on the thermoelectric unit. Accordingly, the efficiency of power generation of the thermoelectric generating module can be enhanced.

### BRIEF DESCRIPTION OF THE DRAWINGS

The invention will become more fully understood from the detailed description and accompanying drawings, which are given for illustration only, and thus are not limitative of the present invention, and wherein:

FIGS. 1 and 2 are schematic diagrams of different aspects of the thermoelectric generating module according to a preferred embodiment of the invention;

FIG. 3 is a schematic diagram of the thermoelectric generating module according to the preferred embodiment of the invention with a light-concentrating unit of reflective type;

FIG. 4 is a schematic diagram of the thermoelectric generating module according to the preferred embodiment of the invention with two light-concentrating units; and

FIG. 5 is a schematic diagram of the thermoelectric generating module according to the preferred embodiment of the invention with a plurality of thermoelectric units.

### DETAILED DESCRIPTION OF THE INVENTION

The present invention will be apparent from the following detailed description, which proceeds with reference to the accompanying drawings, wherein the same references relate to the same elements.

### First Embodiment

As shown in FIG. 1, a thermoelectric generating module 1 according to a preferred embodiment of the invention includes at least a thermoelectric unit 11 and at least a light-concentrating unit 12. The thermoelectric unit 11 has a first surface 111 and a second surface 112 disposed oppositely. The thermoelectric unit 11 includes a plurality of p-type semiconductors and n-type semiconductors connecting to each other. The material of the thermoelectric unit 11 is not limited, and it can be made of semiconductor material, such as lead telluride and alloy thereof, or silicon germanium. Besides, the shape of the thermoelectric unit 11 is also not limited, and it can be rectangular, strip-like, annular, or other shapes. The thermoelectric unit 11 of the embodiment has a rectangular shape, and the semiconductors are sandwiched between two insulated ceramic substrates. The efficiency of power generation of the thermoelectric unit 11, for example, can achieve 1.8% when the temperatures of the two ceramic substrates are 50° C. and 150° C. respectively, and achieve 1.5% when those are 100° C. and 200° C. respectively.

The light-concentrating unit 12 is disposed adjacent to the thermoelectric unit 111 and concentrates a light on the first surface 111 of the thermoelectric unit 11. The light-concentrating unit 12 can be of reflective type or refractive type, and include at least a Fresnel lens, at least a convex lens, a plurality of prisms, or a reflector. As an example, the light-concentrating unit 12 of the embodiment is a convex lens of refractive type.

The light is concentrated on the first surface 111 of the thermoelectric unit 11 by the light-concentrating unit 12. Here, the concentration of the light means the intensity of the light is intensified, but the focus of the light-concentrating unit 12 is not necessarily on the first surface 111. Due to the light concentration caused by the light-concentration unit 12, the temperature of the first surface 111 is obviously higher than that of the second surface 112 on which the light is not concentrated. Based on Seebeck effect, the thermoelectric unit 11 can generate current according to the temperature difference. Furthermore, the thermoelectric generating module 1 includes a plurality of wires W that are electrically connected with the anode and cathode of the thermoelectric unit 11 respectively to transmit the power to external apparatuses.

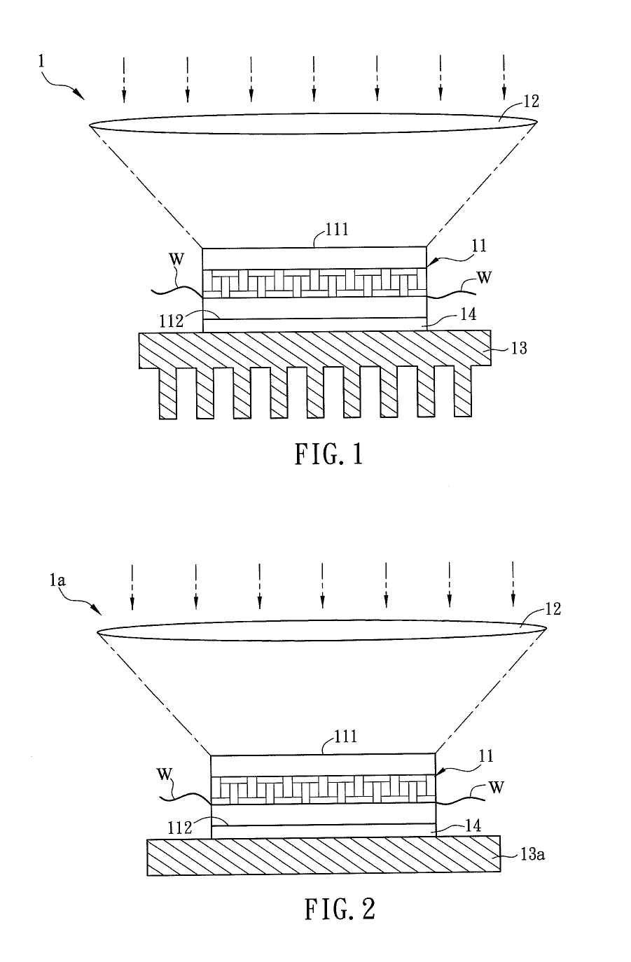

As shown in FIGS. 1 and 2, the thermoelectric generating module 1 and 1a can further include heat-dissipating units 13 and 13a respectively. The heat-dissipating units 13 and 13a are connected to the second surface 112 of the thermoelectric unit 11, and can be, for example, fins, heat sink, plates, heat pipes or other structure for heat dissipating. As shown in FIG. 1, the heat-dissipating unit 13 is a heat-dissipating fin, and the heat-dissipating unit 13a as shown in FIG. 2 is a heat-dissipating plate, e.g. an aluminum plate. The heat-dissipating units 13 and 13a can adhere to the second surface 112 of the thermoelectric unit 11 by the solder paste, phase change material or other heat-conducting material. In the embodiment, the heat-dissipating units 13 and 13a adhere to the second surface 112 by the solder paste. The solder paste, the phase change material or other heat-conducting material can rapidly transmit intense heat to the heat-dissipating units 13 and 13a to cool the second surface 112 and thus increase the temperature difference between the first surface 111 and the second surface 112, so that the output of power generation can be raised.

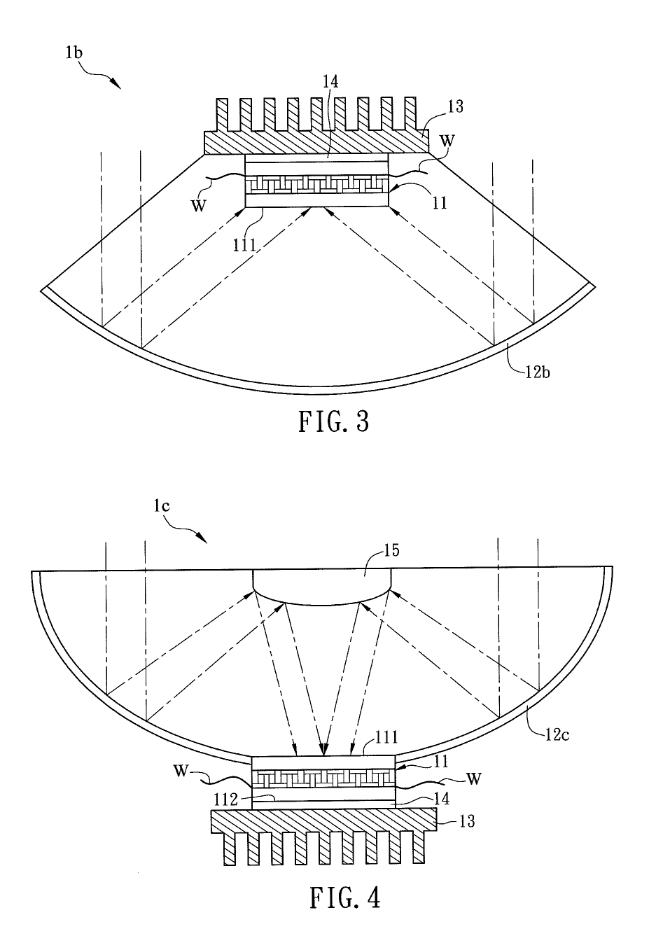

As shown in FIG. 3, different from the above embodiment, the light-concentrating unit 12b of the thermoelectric generating module 1b is of reflective type, such as a reflector with a curved surface or a cup-like surface. In practice, the light-concentrating unit 12b can have a reflective layer disposed on the surface facing the thermoelectric unit 11, or the light-concentrating unit 12b is made of a reflective material. Reflected by the light-concentrating unit 12b, the solar light is concentrated on the first surface 111 of the thermoelectric unit 11.

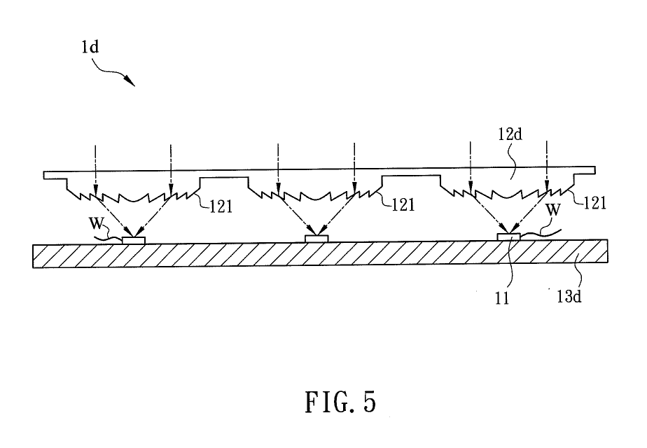

As shown in FIG. 4, different from the above embodiments, the thermoelectric generating module 1c further includes another light-concentrating unit 15. In this embodiment, the light-concentrating unit 12c is a primary reflector, and the light-concentrating unit 15 is a secondary reflector. The light-concentrating unit 15 is disposed substantially at the focus of the light-concentrating unit 12c, and the thermoelectric unit 11 is disposed substantially at the focus of the light-concentrating unit 15. Thereby, the light passes through the light-concentrating units 12c and 15 sequentially and is then concentrated on the first surface 111 of the thermoelectric unit 11. Besides, the light-concentrating unit 12c is connected with the thermoelectric unit 11 by, for example, wedging, screwing or adhering. The light-concentrating unit 15 is disposed opposite to the thermoelectric unit 11.

As shown in FIG. 5, a thermoelectric generating module 1d has a plurality of thermoelectric units 11 disposed on a heat-dissipating unit 13d, and the light-concentrating unit 12d has a plurality of light-concentrating structures 121 that are disposed corresponding to the thermoelectric units 11 respectively to concentrate the light on the thermoelectric units 11 respectively. In the embodiment, the thermoelectric unit 11 can be disposed in a one-dimensional array or two-dimensional array. The thermoelectric units 11 can be electrically connected in series. The generated power can be transmitted by, for example, wires or traces that are disposed on the heat-dissipating unit 13d. In the embodiment, the power is transmitted between the thermoelectric units 11 by the traces, and transmitted to the external apparatuses by wires W.

The light-concentrating structure 121 here is a Fresnel lens for example. The light-concentrating structures 121 can be integrally formed as one piece. Otherwise, the light-concentrating unit 12d can be divided into a plurality of pieces that are disposed corresponding to the thermoelectric units 11 respectively to concentrate the light on the thermoelectric units 11 respectively.

In summary, in the thermoelectric generating module of the invention, the light-concentrating unit concentrates the light on the thermoelectric unit, so that the thermal energy of the light can be concentrated on the thermoelectric unit, and thereby the efficiency of power generation of the thermoelectric generating module can be enhanced. In addition, in a preferred embodiment, the thermoelectric generating module can further include a heat-dissipating unit that can increase the temperature difference between two sides of the thermoelectric unit so as to enhance the efficiency of power generation.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A thermoelectric generating module, comprising:
at least a thermoelectric unit having a first surface and a second surface disposed oppositely; and
at least a light-concentrating unit disposed adjacent to the thermoelectric unit and concentrating a light on the first surface of the thermoelectric unit.

2. The thermoelectric generating module as recited in claim 1, wherein the light-concentrating unit is of reflective type or refractive type.

3. The thermoelectric generating module as recited in claim 1, wherein the light-concentrating unit includes at least a Fresnel lens, at least a convex lens, a plurality of prisms, or a reflector.

4. The thermoelectric generating module as recited in claim 1, further comprising:
a heat-dissipating unit connecting to the second surface.

5. The thermoelectric generating module as recited in claim 4, wherein the heat-dissipating unit is a heat-dissipating fin, a heat-dissipating plate, or a heat pipe.

6. The thermoelectric generating module as recited in claim 1, further comprising:
another light-concentrating unit, wherein the light is concentrated on the first surface of the thermoelectric unit by the light-concentrating units.

7. The thermoelectric generating module as recited in claim 1, wherein when the thermoelectric generating module has a plurality of thermoelectric units, the light-concentrating unit concentrates the light on the thermoelectric units.

8. The thermoelectric generating module as recited in claim 1, wherein when the thermoelectric generating module has a plurality of thermoelectric units, the thermoelectric units are disposed in array.

9. The thermoelectric generating module as recited in claim 1, wherein when the thermoelectric generating module has a plurality of thermoelectric units and a plurality of light-concentrating units, the light-concentrating units concentrate the light on the thermoelectric units respectively.

10. The thermoelectric generating module as recited in claim 1, wherein when the thermoelectric generating module has a plurality of thermoelectric units, the thermoelectric units are electrically connected in series.
